(19) United States
(12) Patent Application Publication
(10) Pub. No.: US 2013/0292852 A1
(43) Pub. Date: Nov. 7, 2013

(54) CHIP EMBEDDED PACKAGES AND METHODS FOR FORMING A CHIP EMBEDDED PACKAGE

(71) Applicants: Edward FUERGUT, Dasing (DE); Horst THEUSS, Wenzenbach (DE)

(72) Inventors: Edward FUERGUT, Dasing (DE); Horst THEUSS, Wenzenbach (DE)

(73) Assignee: INFINEON TECHNOLOGIES AG, Neubiberg (DE)

(21) Appl. No.: 13/462,868

(22) Filed: May 3, 2012

(51) Int. Cl. H01L 23/52; H01L 21/78

(52) U.S. Cl. 257/777; 438/113; 257/E23.141; 257/E21.599

(57) ABSTRACT

A chip embedded package is provided, the chip embedded package including: a plurality of dies; wherein a first die of the plurality of dies is a chip implementing a first sensor technology, and wherein a second die of the plurality of dies is a chip implementing a second sensor technology; and wherein the plurality of dies are molded with an encapsulation material; wherein at least one of the first die and the second die includes a film interconnect.

### TECHNICAL FIELD

Chip embedded packages and methods for forming a chip embedded package

### BACKGROUND

Precise and inexpensive sensors, e.g. those used in navigation assistances, are required to determine various measurements, e.g. position, speed, acceleration, angles in space. It is challenging to produce precise and inexpensive sensors and to achieve greater precision in the measurements, particularly for three-dimensional systems, for example for use in mobile devices, e.g. smart phones, and automotive applications.

### SUMMARY

Various embodiments provide a chip embedded package, including: a plurality of dies; wherein a first die of the plurality of dies is a chip implementing a first sensor technology, and wherein a second die of the plurality of dies is a chip implementing a second sensor technology; and wherein the plurality of dies are molded with an encapsulation material; wherein at least one of the first die and the second die includes a film interconnect.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a chip embedded package according to an embodiment;

FIG. 2 shows a method for forming a chip embedded package according to an embodiment;

FIGS. 3A to 3D show a method for forming a chip embedded package according to an embodiment;

FIGS. 3E shows a chip embedded package according to an embodiment;

FIGS. 4A and 4B show a top view and side view of a chip embedded package according to an embodiment;

FIG. 5 shows a chip embedded package according to an embodiment;

FIG. 6 shows a method for forming a chip embedded package according to an embodiment.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments provide a package, wherein sensor chips with different technologies may be mounted in the package, e.g. a chip embedded package such as e.g. a wafer level package (wherein the wafer has e.g. a round shape) or a panel level package (wherein the panel has e.g. a polygonal shape, e.g. a rectangular shape, e.g. a square shape). In various embodiment, “chip embedded package” may be understood a packaging, e.g. encapsulating, of a plurality of dies or chips being mounted on one common carrier.

Various embodiments provide a package, wherein one or more sensor chips may be encapsulated in a chip embedded package, wherein at least one sensor chip is configured to implement a different sensor technology from another sensor chip.

Various embodiments provide a chip embedded package, e.g. a chip embedded package, wherein sensors may be configured to detect position, speed, acceleration, angles in space, e.g. three-dimensional space, six-dimensional space, nine-dimensional space.

Various embodiments provide a package wherein a mechanical sensor and a magnetic sensor may be embedded in a chip embedded package.

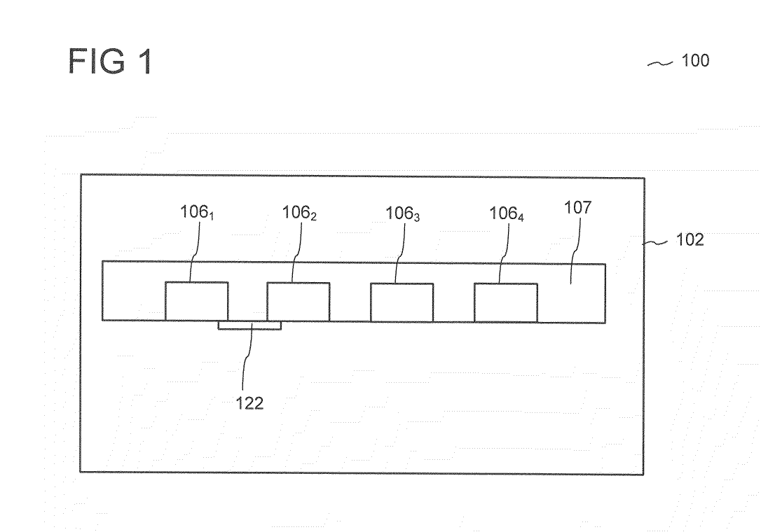

FIG. 1 shows chip embedded package 102 according to an embodiment.

Chip embedded package 102 may include a plurality of dies 106₁, 106₂, 106₃, 106₄ . . . 106ₙ; wherein a first die e.g. die 106₁ of the plurality of dies 106₁, 106₂, 106₃, 106₄ . . . 106ₙ, is a chip implementing a first sensor technology, and wherein a second die, e.g. die 106₂ of the plurality of dies 106₁, 106₂, 106₃, 106₄ . . . 106ₙ, is a chip implementing a second sensor technology; and wherein at least one of the first die, e.g. die 106₁, and the second die, e.g. die 106₂, includes a film interconnect 122.

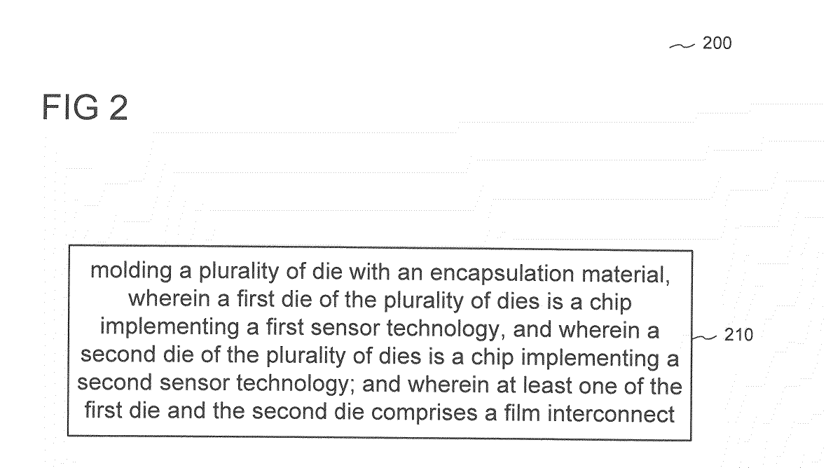

FIG. 2 shows method 200 for manufacturing a chip embedded package according to an embodiment. Method 200 may include

molding a plurality of die with an encapsulation material, wherein a first die of the plurality of dies is a chip implementing a first sensor technology, and wherein a second die of the plurality of dies is a chip implementing a second sensor technology; and wherein at least one of the first die and the second die comprises a film interconnect (in 210).

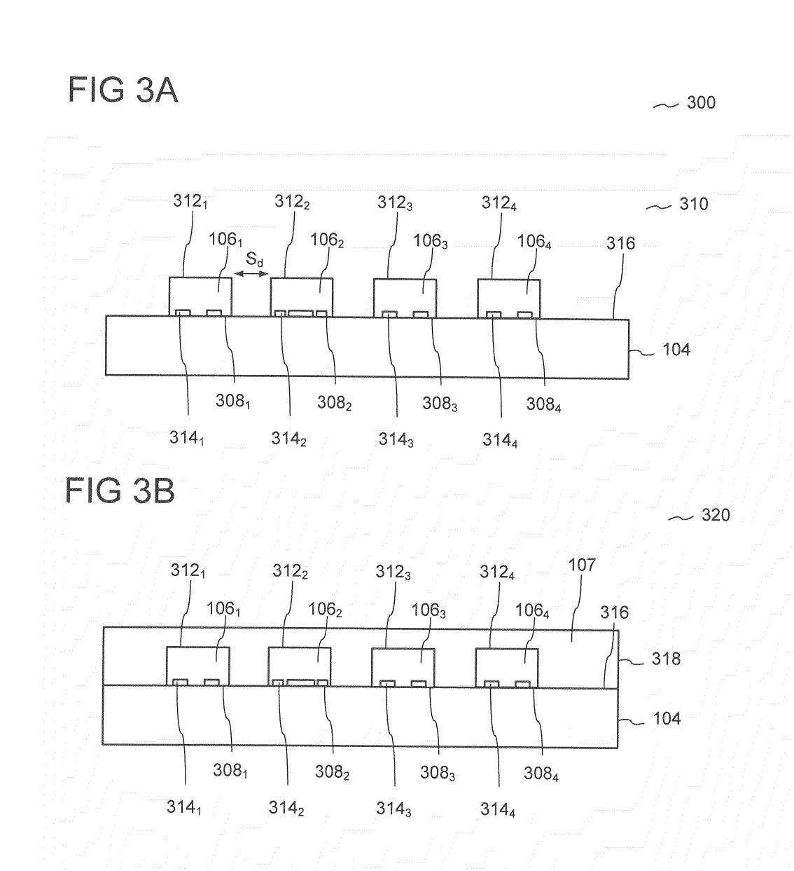

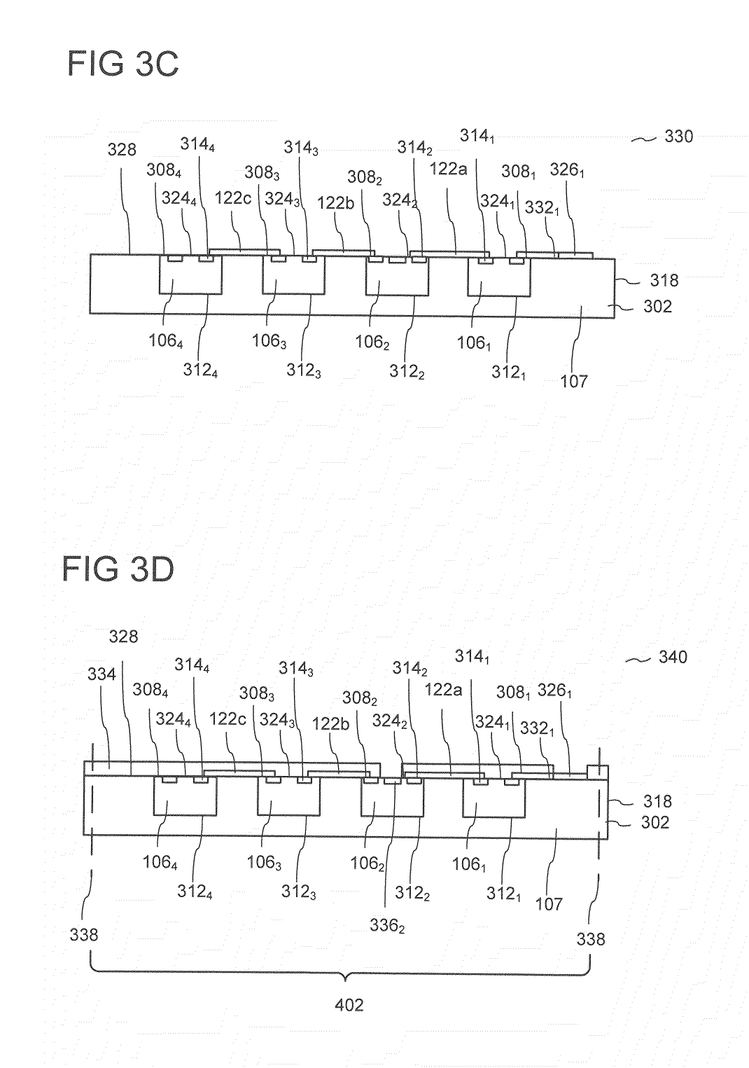

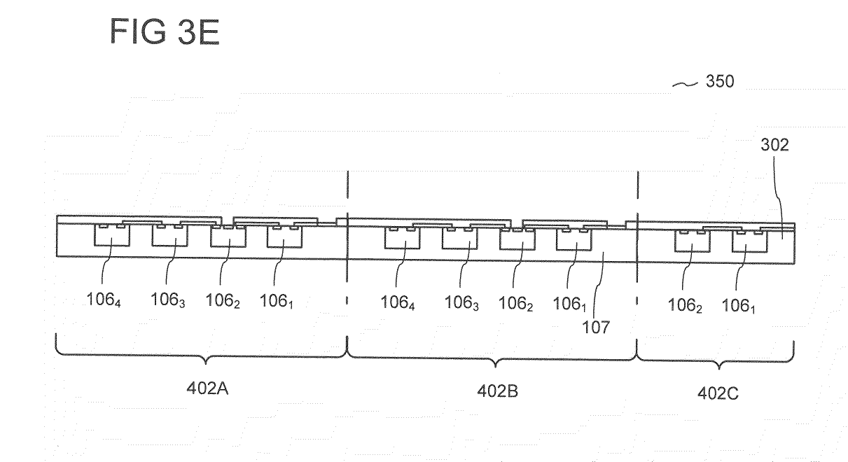

FIGS. 3A to 3D show method 300 for manufacturing a chip embedded package according to an embodiment.

Method 300 may include molding a plurality of die with an encapsulation material, wherein a first die of the plurality of dies is a chip implementing a first sensor technology, and wherein a second die of the plurality of dies is a chip implementing a second sensor technology; and wherein at least one of the first die and the second die comprises a film interconnect.

In 310, plurality of dies 106₁, 106₂, 106₃, 106₄ . . . 106ₙ may be disposed over carrier 104. This process may be carried out using a “pick and place” process, wherein plurality of dies 106₁, 106₂, 106₃, 106₄ . . . 106ₙ may include dies, e.g. “good” dies which have passed a quality control test. Four dies 106₁, 106₂, 106₃, 106₄ are shown FIG. 1, however, plurality of dies 106₁, 106₂, 106₃, 106₄ . . . 106ₙ may not be limited to four but may include one or more dies, e.g. two, three, four, five, six, seven, eight, nine, ten or even more dies such as tens, hundreds or thousands of dies. Plurality of dies 106₁, 106₂, 106₃, 106₄ . . . 106ₙ may therefore each be initially individually separated from each other as they are selected and placed, e.g. sequentially place, over common carrier 104. Subsequently, once plurality of dies 106₁, 106₂, 106₃, 106₄ . . . 106ₙ are placed over carrier 104, they may be processed in order to form a reconstituted wafer, e.g. in an embedded wafer level process.

Each die of plurality of dies 106₁, 106₂, 106₃, 106₄ . . . 106ₙ may be defined by a length x breadth dimension. According an embodiment, each die may include a 200 μm×200 μm die. According to another embodiment, each die may include a 300 μm×300 μm die. According to another embodiment, the plurality of dies 106₁, 106₂, 106₃, 106₄ . . . 106ₙ may have a different length×breadth dimension from each other, e.g. die 106₁ may have a different length×breadth dimension from die 106₂.

At least one of plurality of dies 106₁, 106₂, 106₃, 106₄ . . . 106ₙ may have a thickness (from top side to bottom side) ranging from about 5 μm to about 800 μm, e.g. from about 10 μm to about 400 μm, e.g. from about 50 μm to about 250 μm.

At least one of plurality of dies 106₁, 106₂, 106₃, 106₄ . . . 106ₙ may have a length ranging from about 100 μm to 10 mm, e.g. about 200 μm to 8 mm, e.g. about 500 μm to about 5 mm.

At least one of plurality of dies 106₁, 106₂, 106₃, 106₄ . . . 106ₙ may have a breadth ranging from about 100 μm to 10 mm, e.g. about 200 μm to 8 mm, e.g. about 500 μm to about 5 mm.

At least one of plurality of dies 106₁, 106₂, 106₃, 106₄ . . . 106ₙ may include at least part of a wafer substrate. Alternatively, each of plurality of dies 106₁, 106₂, 106₃, 106₄ . . . 106ₙ may include at least part of a wafer substrate. At least one of plurality of dies 106₁, 106₂, 106₃, 106₄ . . . 106ₙ may include one or more electronic circuits formed within the wafer substrate.

At least one die 106₁ of plurality of dies 106₁, 106₂, 106₃, 106₄ . . . 106ₙ may include a top side 308₁. Top sides 308₁, 308₂, 308₃, 308₄ . . . 308ₙ may be understood to refer to the sides of plurality of dies 106₁, 106₂, 106₃, 106₄ . . . 106ₙ which carries one or more contact pads 314₁, 314₂, 314₃, 314₄ . . . 314ₙ or electrical contacts, wherein bonding pads or electrical connects may be attached. Top sides 308₁, 308₂, 308₃, 308₄ . . . 308ₙ may be understood to refer to the sides of plurality of dies 106₁, 106₂, 106₃, 106₄ . . . 106ₙ which are mostly covered by metallization layers.

One or more electronic circuits formed in plurality of dies 106₁, 106₂, 106₃, 106₄ . . . 106ₙ may be formed at the top sides 308₁, 308₂, 308₃, 308₄ . . . 308ₙ of plurality of dies 106₁, 106₂, 106₃, 106₄ . . . 106ₙ.

Bottom sides 312₁, 312₂, 312₃, 312₄ . . . 312ₙ may be understood to refer to sides of plurality of dies 106₁, 106₂, 106₃, 106₄ . . . 106ₙ which may be free from metallization or contact pads or electrical contacts.

Top sides 308₁, 308₂, 308₃, 308₄ . . . 308ₙ may face a direction substantially opposite to a direction which bottom sides 312₁, 312₂, 312₃, 312₄ . . . 312ₙ face.

Top sides 308₁, 308₂, 308₃, 308₄ . . . 308ₙ may also be referred to as a “first side”, “front side” or “upper side” of plurality of dies 106₁, 106₂, 106₃, 106₄ . . . 106ₙ. The terms “top side”, “first side”, “front side” or “upper side” may be used interchangeably hereinafter. Bottom sides 312₁, 312₂, 312₃, 312₄ . . . 312ₙ may also be referred to as “second side” or “back side” of plurality of dies 106₁, 106₂, 106₃, 106₄ . . . 106ₙ. The terms “second side”, “back side”, or “bottom side” may be used interchangeably hereinafter.

Carrier 104 may include an electrically insulating material or an electrically conductive and/or semiconductive material, the electrically insulating material including at least one from the following group of materials, the group consisting of: plastic, glass, metal, silicon, an organic material.

Carrier 104 may provides a substantially level supporting structure over which plurality of dies 106₁, 106₂, 106₃, 106₄ . . . 106ₙ may be arranged such that plurality of dies 106₁, 106₂, 106₃, 106₄ . . . 106ₙ may be arranged substantially level with each other. Top sides 308₁, 308₂, 308₃, 308₄ . . . 308ₙ of plurality of dies 106₁, 106₂, 106₃, 106₄ . . . 106ₙ may be placed over carrier first side 316, wherein top sides 308₁, 308₂, 308₃, 308₄ . . . 308ₙ may face carrier first side 316. Therefore, top sides 308₁, 308₂, 308₃, 308₄ . . . 308ₙ of plurality of dies 106₁, 106₂, 106₃, 106₄ . . . 106ₙ may be arranged substantially level with each other over carrier 104.

One or more of plurality of dies 106₁, 106₂, 106₃, 106₄ . . . 106ₙ may include a chip, e.g. a semiconductor chip. The semiconductor chip may include at least part of a wafer substrate, wherein the wafer substrate may include a material, e.g. a semiconductor material. The wafer substrate may include at least one from the following group of materials, the group of materials consisting of: Silicon, Germanium, Group III to V materials, polymers. According to an embodiment, the wafer substrate may include doped or undoped silicon. According to another embodiment, the wafer substrate may include a silicon on insulator SOI wafer. According to an embodiment, the wafer substrate may include a semiconductor compound material, e.g. gallium arsenide (GaAs), indium phosphide (InP), gallium nitride (GaN), silicon germanium (SiGe), silicon carbide (SiC). According to an embodiment, the wafer substrate may include a quaternary semiconductor compound material, e.g. indium gallium arsenide (InGaAs).

First die, e.g. die 106₁ of plurality of dies 106₁, 106₂, 106₃, 106₄ . . . 106ₙ may be a chip, e.g. including one or more electronic circuits, implementing a first sensor technology. Second die, e.g. die 106₂ of plurality of dies 106₁, 106₂, 106₃, 106₄ . . . 106ₙ may be a chip, e.g. including one or more electronic circuits, implementing a second sensor technology. The first sensor technology may be different from the second sensor technology.

At least one of the first sensor technology and the second sensor technology may include a sensor technology from the following group of sensor technologies, the group consisting of: magnetic sensor technology, gyroscopic sensor technology, motion sensor technology, acceleration sensor technology, pressure sensor technology.

At least one of the first sensor technology and the second sensor technology may include a sensor technology from the following group of sensor technologies, the group consisting of: magnetic sensor technology, gyroscopic sensor technology, motion sensor technology, acceleration sensor technology, pressure sensor technology, photosensor technology, gas sensor technology, chemical sensor technology, biological sensor technology, current sensor technology, biometric sensor technology, e.g. fingerprint sensor.

A die implementing magnetic sensor technology may include a die including a sensing portion which responds to a change in direction, e.g. orientation and one or more electronic components which may convert the response of the sensor portion to the stimulus into a signal, e.g. an electrical signal.

A die implementing gyroscopic sensor technology may include a die including a sensing portion which responds to a magnetic stimulus, e.g. a magnetic field, and one or more electronic components which may convert the response of the sensor portion to the magnetic stimulus into a signal, e.g. an electrical signal.

A die implementing motion sensor technology may include a die including a sensing portion which responds to a change in motion, e.g. displacement and one or more electronic components which may convert the response of the sensor portion to the stimulus into a signal, e.g. an electrical signal.

A die implementing acceleration sensor technology may include a die including a sensing portion which responds to acceleration e.g. a change in velocity and one or more electronic components which may convert the response of the sensor portion to the stimulus into a signal, e.g. an electrical signal.

A die implementing pressure sensor technology may include a die including a sensing portion which responds to pressure and one or more electronic components which may convert the response of the sensor portion to the stimulus into a signal, e.g. an electrical signal.

A die implementing photosensor technology may include a die including a sensing portion which responds to electromagnetic waves, e.g. light, and one or more electronic components which may convert the response of the sensor portion to the stimulus into a signal, e.g. an electrical signal.

A die implementing gas sensor technology may include a die including a sensing portion which responds to gases, e.g. chemical elements, e.g. chemical compounds, and one or more electronic components which may convert the response of the sensor portion to the stimulus into a signal, e.g. an electrical signal.

A die implementing biological sensor technology may include a die including a sensing portion which responds to biological and/or chemical species, and one or more electronic components which may convert the response of the sensor portion to the stimulus into a signal, e.g. an electrical signal.

At least one of the first sensor technology and the second sensor technology may include at least one sensor from the following group of sensors, the group consisting of: a mechanical sensor, an electrical sensor, and electromechanical sensor, a microelectromechanical sensor. For example, the first sensor technology and the second sensor technology may relay on the movement of mechanical parts in the sensing portion for the generation of a measurable signal.

A measurable signal in response to the stimulus in the sensing portion may include an electrical signal, e.g. a resistive signal, e.g. a capacitive signal, e.g. a current signal, e.g. a voltage signal, e.g. an inductive signal.

In 320, plurality of dies 106₁, 106₂, 106₃, 106₄ . . . 106ₙ may be commonly molded with encapsulation material 107 over carrier 104. For example, plurality of dies 106₁, 106₂, 106₃, 106₄ . . . 106ₙ may be covered with the same encapsulation material 107 over the same carrier 104. Plurality of dies 106₁, 106₂, 106₃, 106₄ . . . 106ₙ may be covered with the same encapsulation material 107 in a single process.

Encapsulation material 107 may include at least one from the following group of materials, the group consisting of: filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

Encapsulation material 107 may be deposited over bottom sides 312₁, 312₂, 312₃, 312₄ . . . 312ₙ of plurality of dies 106₁, 106₂, 106₃, 106₄ . . . 106ₙ. Encapsulation material 107 may be deposited between plurality of dies 106₁, 106₂, 106₃, 106₄ . . . 106ₙ. For example, encapsulation material 107 may be deposited between first die, e.g. die 106₁, and second die, e.g. die 106₂. In other words, encapsulation material 107 may be deposited in spaces between adjacent dies of plurality of dies 106₁, 106₂, 106₃, 106₄ . . . 106ₙ, e.g. between first die, e.g. die 106₁, and second die, e.g. die 106₂, between second die, e.g. die 106₂ and third die, e.g. die 106₃ and so forth. As top sides 308₁, 308₂, 308₃, 308₄ . . . 308ₙ may be displaced on carrier 104, top sides 308₁, 308₂, 308₃, 308₄ . . . 308ₙ may be substantially free of encapsulation material 107.

It may be understood that plurality of dies 106₁, 106₂, 106₃, 106₄ . . . 106ₙ may include an array of a plurality of dies 106₁, 106₂, 106₃, 106₄ . . . 106ₙ for example a 2×2 dimensional array of a plurality of dies 106₁, 106₂, 106₃, 106₄ . . . 106ₙ. Therefore, encapsulation material 107 may be deposited between adjacent rows and/or columns of plurality of dies 106₁, 106₂, 106₃, 106₄ . . . 106ₙ. Encapsulation material 107 may at least partially surround each die of plurality of dies 106₁, 106₂, 106₃, 106₄ . . . 106ₙ. Encapsulation material 107 may be formed over bottom sides 312₁, 312₂, 312₃, 312₄ . . . 312ₙ and one or more sidewalls of plurality of dies 106₁, 106₂, 106₃, 106₄ . . . 106ₙ. The one or more sidewalls may refer to sides of plurality of dies 106₁, 106₂, 106₃, 106₄ . . . 106ₙ, extending between top sides 308₁, 308₂, 308₃, 308₄ . . . 308ₙ and bottom sides 312₁, 312₂, 312₃, 312₄ . . . 312ₙ.

Adjacent dies of plurality of dies 106₁, 106₂, 106₃, 106₄ . . . 106ₙ may be separated by a separation distance Sd. Separation distance Sd may range from about 10 μm to about 10 mm.

It may be understood that plurality of dies 106₁, 106₂, 106₃, 106₄ . . . 106ₙ may be arranged over common carrier 104. Furthermore, encapsulation material 107 may be deposited over, e.g. to cover, plurality of dies 106₁, 106₂, 106₃, 106₄ . . . 106ₙ in a batch process, e.g. simultaneously. The batch process wherein plurality of dies 106₁, 106₂, 106₃, 106₄ . . . 106ₙ may be embedded, e.g. covered, with encapsulation material 107 together, instead of being individually treated, e.g. covered, may be referred to as a common molding process, wherein plurality of dies 106₁, 106₂, 106₃, 106₄ . . . 106ₙ may be held together in single structure 318 by encapsulation material 107.

It may be understood that plurality of dies 106₁, 106₂, 106₃, 106₄ . . . 106ₙ may include, in addition to chips implementing sensor technologies, further dies, and/or further electronic components, e.g. logic devices, e.g. passive devices, e.g. active devices. One or more further dies of plurality of dies 106₁, 106₂, 106₃, 106₄ . . . 106ₙ may each include at least one from the following group of devices, the group of devices consisting of: a logic device, a passive device, an active device. A logic device may include at least one from the following group of the devices, the group consisting of: an application specific integrated circuit ASIC, a driver, a controller, a memory, a sensor. A passive device may include at least one from the following group of the devices, the group consisting of: a resistor, a capacitor, and inductor. An active device may include at least one from the following group of the devices, the group consisting of: semiconductor devices, transistors, power devices, power transistors, MOS transistors, bipolar transistors, field effect transistors, insulated gate bipolar transistors, thyristors, MOS controlled thyristors, silicon controlled rectifiers, schottky diodes, silicon carbide diodes, gallium nitride devices, aluminum nitride devices. The devices may be implemented as integrated circuits having a plurality of semiconductor devices, e.g. hundreds, thousands or millions or even more semiconductor devices.

According to an embodiment, first die, e.g. die 106₁ may include a chip implementing a first sensor technology, second die, e.g. die 106₂ may include a chip implementing a second sensor technology. Third die, e.g. die 106₃ may include optionally another chip implementing a third sensor technology. Fourth die, e.g. die 106₄ may include a further device, e.g. a logic device. A fifth die (not shown), e.g. die 106₅ may include a further device, e.g. an active device. A sixth die (not shown), e.g. die 106₆ may include a further device, e.g. a passive device.

After deposition of encapsulation material 107 over plurality of dies 106₁, 106₂, 106₃, 106₄ . . . 106ₙ, carrier 104 may be removed. Structure 318 including plurality of dies 106₁, 106₂, 106₃, 106₄ . . . 106ₙ and encapsulation material 107 may be released from carrier 104. Structure 318 may include a reconstituted wafer including plurality of dies 106₁, 106₂, 106₃, 106₄ . . . 106ₙ and encapsulation material 107, wherein plurality of dies 106₁, 106₂, 106₃, 106₄ . . . 106ₙ may be commonly molded, e.g. covered by encapsulation material 107, and wherein top sides 308₁, 308₂, 308₃, 308₄ . . . 308ₙ of plurality of dies 106₁, 106₂, 106₃, 106₄ . . . 106ₙ may be arranged substantially level with each other, and wherein top sides 308₁, 308₂, 308₃, 308₄ . . . 308ₙ may be substantially free from encapsulation material 107 for subsequent processes.

Subsequently, in 330, redistribution layers and passivation layers may be deposited over top sides 308₁, 308₂, 308₃, 308₄ . . . 308ₙ of plurality of dies 106₁, 106₂, 106₃, 106₄ . . . 106ₙ.

Method 300 may further include forming one or more electrically conductive portions 122a, 122b, 122c over a first side 328 of chip embedded package 302; wherein at least one electrically conductive portion 122a of the one or more electrically conductive portions may electrically connect first die, e.g. die 106₁ to the second die, e.g. die 106₂, and wherein at least one further electrically conductive portion 122b of the one or more electrically conductive portions 122a, 122b, 122c may electrically connect at least one of the first die, e.g. die 106₁ and the second die, e.g. die 106₂ to one or more further dies of the plurality of dies, e.g. active and/or passive and/or logic components. One or more electrically conductive portions 122a, 122b, 122c may be deposited over top sides 308₁, 308₂, 308₃, 308₄ . . . 308ₙ.

One or more electrically conductive portions 122a, 122b, 122c may each include a film interconnect, e.g. 122, wherein at least one of first die e.g. die 106₁ and second die e.g. die 106₂ may include film interconnect 122.

At least one of first die e.g. die 106₁ and second die e.g. die 106₂ may be electrically interconnected, directly and/or indirectly, to at least one of third die, e.g. die 106₃, fourth die, e.g. die 106₄, and fifth die (not shown) via one or more electrically conductive portions i.e. electrical interconnects, e.g. 122a, 122b, 122c and/or other electrically conductive portions not shown in the figures. The one or more electrically conductive portions i.e. electrical interconnects, e.g. 122a, 122b, 122c may also be referred to as a redistribution layer. At least one of first die e.g. die 106₁ and second die e.g. die 106₂ may be electrically interconnected, directly and/or indirectly, via one or more contact pads formed over their front sides, i.e. top sides 308₁, 308₂ to one or more contact pads formed over the front sides, i.e. top sides 308₃, 308₄, 308₅ of at least one of third die, e.g. die 106₃, fourth die, e.g. die 106₄, and fifth die (not shown). For example, second die e.g. die 106₂ and third die e.g. die 106₃ may be electrically interconnected via one or more electrically conductive portions 122b. Third die e.g. die 106₃ and fourth die e.g. die 106₄ may be electrically interconnected via one or more electrically conductive portions 122c. As an example, one or more contact pads 314₁ belonging to first die e.g. die 106₁ may be electrically interconnected via one or more electrically conductive portions, e.g. 122a, to one or more contact pads 314₂ belonging to second die e.g. die 106₂. One or more contact pads 314₁, 314₂, 314₃, 314₄, formed over the top sides of the plurality of dies provide an electrical interconnect area for electrically interconnecting the chip to other chips and/or to other devices, e.g. active devices, e.g. logic devices, e.g. passive devices. Other areas, e.g. surface areas of the plurality of dies 106₁, 106₂, 106₃, 106₄ . . . 106ₙ not covered by one or more contact pads 314₁, 314₂, 314₃, 314₄ may be covered with electrically insulating material 324₁, 324₂, 324₃, 324₄ to electrically insulate the other areas of the plurality of dies 106₁, 106₂, 106₃, 106₄ . . . 106ₙ from their surroundings. For example at least one die, e.g. one or more dies, e.g. substantially all the dies, from the plurality of dies 106₁, 106₂, 106₃, 106₄ . . . 106ₙ may be covered with encapsulation material 107 on their bottom sides 312₁, 312₂, 312₃, 312₄ . . . 312ₙ and on their sidewalls.

It may also be understood that contact pads formed over the dies may also be electrically insulated from each other. Using die 106₁ as an example, electrically insulating material 324 may be formed, over and/or on top side 308₁, wherein electrically insulating material 324, e.g. a dielectric material, may be deposited over areas of top side 308₁ not covered by one or more contact pads 314₁. If more than one contact pad 314₁ is formed over top side 308₁, each of one or more contact pads 314₁ may therefore, be electrically isolated from each other. For example, a first of one or more contact pads 314₁ may be electrically isolated from a second of one or more contact pads 314₁ by an electrically insulating material 324, e.g. silicon dioxide, formed over top side 308₁. Alternatively, encapsulation material 107 may be used instead of or in addition to electrically insulating material 324 to electrically isolate first of one or more contact pads 314₁ from a second of one or more contact pads 314₁.

One or more electrically conductive portions e.g. electrically conductive portions 122a, 122b, 122c and any other electrically conductive portions not included in the figures may be deposited in a single process, according to at least one of the following methods. For example by galvanic deposition, electroplating, galvanic electroplating, evaporation, sputtering, chemical deposition, chemical vapor deposition, electroless deposition such as e.g. electroless plating. These methods may be used to form the film interconnect.

One or more electrically conductive portions e.g. electrically conductive portions 122a, 122b, 122c may include a thin film interconnect, e.g. ranging from about 2 nm to about 1 μm, e.g. from about 5 nm to about 500 nm, e.g. from about 10 nm to about 200 nm.

One or more electrically conductive portions e.g. electrically conductive portions 122a, 122b, 122c may include a thin film interconnect, e.g. ranging from about 1 μm to about 50 μm, e.g. from about 5 μm to about 30 μm, e.g. from about 10 μm to about 20 μm.

One or more electrically conductive portions e.g. electrically conductive portions 122a, 122b, 122c may include at least one material, element or alloy from the following group of materials, the group consisting of: copper, aluminum, silver, tin, gold, palladium, zinc, nickel, iron.

One or more contact pads 314₁, 314₂, 314₃, 314₄, may include at least one material, element or alloy from the following group of materials, the group consisting of: copper, aluminum, silver, tin, gold, palladium, zinc, nickel, iron.

One or more electrically conductive portions 122a, 122b, 122c may include at least one from the following group of electrically conductive portions, the group consisting of: galvanically deposited interconnects, sputtered interconnects, evaporated interconnects, plated interconnects.

In addition to the deposition of one or more electrically conductive portions 122a, 122b, 122c, one or more electrical contacts, e.g. 326₁ may be deposited. Method 300 may further include forming one or more electrical contacts, e.g. 326₁ over first side 328 of chip embedded package 302 and electrically connecting one or more electrical contacts, e.g. 326₁ to at least one of the first die, e.g. die 106₁ and the second die, e.g. 106₂; and forming one or more electrically insulating portions 334 over the one or more electrically conductive portions 122a, 122b, 122c.

One or more electrical contacts, e.g. 326₁ may be deposited over top side 328 of structure 318. Top side 328 of structure 318 may include a side of structure 318 which may be substantially level with top sides 308₁, 308₂, 308₃, 308₄ . . . 308ₙ of plurality of dies 106₁, 106₂, 106₃, 106₄ . . . 106ₙ, as top side 328 may be part of the reconstituted wafer which was disposed over carrier 104. One or more electrical contacts, e.g. 326₁ may be deposited over encapsulation material 107 on structure top side 328. One or more electrical contacts, e.g. 326₁ may include at least one material, element or alloy from the following group of materials, the group consisting of: copper, aluminum, silver, tin, gold, palladium, zinc, nickel, iron.

At least one of first die e.g. die 106₁ and second die e.g. die 106₂ may be electrically interconnected, directly and/or indirectly, to one or more electrical contacts, e.g. 326₁ via one or more further electrically conductive portions, e.g. 332₁. For example, as shown in FIG. 3D, first die, e.g. die 106₁, may electrically connected to one or more electrical contacts e.g. to electrical contact 326₁ via further electrical interconnect 332₁.

It may be understood that although only on electrically contact 326₁ is shown in FIG. 3D, the number of one or more electrical contacts is not limited to one and may include any number more than one. Second die, e.g. die 106₂, third die e.g. die 106₃, fourth die e.g. die 106₄ and/or fifth die, e.g. die 106₅ may be electrically interconnected to one or more electrical contacts 326₁, 326₂, 326₃ . . . 326ₙ via one or more further electrically conductive portions 332₁, 3122, 332₃ . . . 332ₙ.

In 340, passivation layer 334 may be deposited over structure top side 328. Passivation layer 334 may be deposited over encapsulation material 107 over structure top side 328. Passivation layer 334 may be deposited over one or more electrically conductive portions 122a, 122b, 122c. Passivation layer 334 may be deposited over one or more electrical contacts 326. Passivation layer 334 may be deposited over one or more further electrically conductive portions 332₁, 3122, 332₃ . . . 332ₙ. Portions of passivation layer 334 may be selectively removed such that selected areas of the chip embedded package may be released from passivation layer 334 i.e. not covered by passivation layer 334. For example selected sensing areas e.g. sensing area 336₂, may be released from passivation layer 334. In other words, sensing area 336₂ may not be covered by passivation layer 334. Furthermore, one or more electrical contacts 326₁, 326₂, 326₃ . . . 326ₙ may be released from passivation layer 334, i.e. may not be covered by passivation layer 334. According to an alternative process according to an embodiment, passivation layer 334 may be selectively deposited in some areas and not deposited in selected areas e.g. sensing area 336₂, e.g. areas of one or more electrical contacts 326₁, 326₂, 326₃ . . . 326ₙ.

Passivation layer 334 may be deposited, such that passivation layer 334 may at least partially surround one or more electrically conductive portions 122a, 122b, 122c, e.g. electrically insulating each of one or more electrically conductive portions 122a, 122b, 122c from its surroundings, and from each other.

Passivation layer 334 may include an electrically insulating material. Passivation layer 334 may include at least one from the following group of materials, the group consisting of silicon dioxide, silicon nitride. Passivation layer 334 may include at least one from the following group of materials, the group consisting of filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

As structure 318 is at least part of a chip embedded package, processing thus far, and subsequent handling of the sensors, e.g. the dies including sensors, may be carried out on a single chip embedded package, instead of on individual dies. According to various embodiments, chip embedded package 102 e.g. structure 318 may have a thickness ranging from about 500 μm to about 1 mm, e.g. about 200 μm to 1 mm. e.g. about 100 μm to 1 mm.

Method 300 may further include electrically connecting the one or more electrical contacts 326₁, 326₂, 326₃ . . . 326ₙ to an external electrical circuit, e.g. a testing circuit, for testing the plurality of dies 106₁, 106₂, 106₃, 106₄ . . . 106ₙ. Subsequently separating the plurality of dies 106₁, 106₂, 106₃, 106₄ . . . 106ₙ may be carried out, wherein a separated portion, e.g. chip package 402 shown later, may include the first die, e.g. 106₁ and the second die, e.g. 106₂. The separated chip package 402 may include at least one of the first die, e.g. 106₁ and the second die, e.g. 106₂. Before the separation, testing may be carried out to ensure that one or more electrical circuits, e.g. electrically interconnections between plurality of dies 106₁, 106₂, 106₃, 106₄ . . . 106ₙ may be functioning correctly. Furthermore, testing may be carried out to determine whether or not the integrity of first die, e.g. 106₁ and the second die, e.g. 106₂ are functioning properly. For example, the integrity of the connections of one or more electrically conductive portions 122a, 122b, 122c and/or one or more further electrically conductive portions 332₁, 312₂, 332₃ . . . 332ₙ may be tested. Furthermore, the quality of one or more electrical contacts 326₁, 326₂, 326₃ . . . 326ₙ may be tested.

It may be understood that a group of one or more electrical contacts 326₁, 326₂, 326₃ . . . 326ₙ may include test contacts which may be used primarily for the testing of the integrity of the electrical interconnections connecting plurality of dies 106₁, 106₂, 106₃, 106₄ . . . 106ₙ. Another group of the one or more electrical contacts 326₁, 326₂, 326₃ . . . 326ₙ may include electrical contacts which may be used during the implementation of the actual product, and not for testing. It may also be understood that a group of one or more electrical contacts 326₁, 326₂, 326₃ . . . 326ₙ may have a dual function as a test contact as well as an electrical contact for the implementation of the product.

One or more microcontroller circuits may be electrically contacted to one or more electrical contacts 326₁, 326₂, 326₃ . . . 326ₙ, wherein an electrical circuit including at least one of plurality of dies 106₁, 106₂, 106₃, 106₄ . . . 106ₙ, at least one of one or more electrically conductive portions 122a, 122b, 122c and/or at least one of one or more further electrically conductive portions 332₁, 3122, 332₃ . . . 332ₙ, may be tested. It may be understood that one or more testing circuits, which may be used for testing may also be embedded in the reconstituted wafer, i.e. structure 318. The one or more testing circuits may be electrically connected to plurality of dies 106₁, 106₂, 106₃, 106₄ . . . 106ₙ, e.g. the one or more integrated circuits may be electrically connected to at least one plurality of dies 106₁, 106₂, 106₃, 106₄ . . . 106ₙ, e.g. first die, e.g. die 106₁, e.g. second die, e.g. die 106₂. The one or more integrated circuits may be discarded and/or separated from individual chip packages as a result of the separation process.

Optionally, a solder mount, step may be carried before or after testing. If required, solder material, e.g. a solder bump, e.g. a solder ball which may include e.g. a soft solder, e.g. a diffusion solder, may be deposited over at least a portion of the one or more electrical contacts 326₁, 326₂, 326₃ . . . 326ₙ. The solder mount may be used for subsequently electrically connecting the chip packages to a circuit board.

Subsequently, after testing, separation of individual chip packages, e.g. along separation lines 338, may be carried out. Properly functioning dies may be separated from defective dies when separating into the individual chip packages.

It may be understood that according to various embodiments, at least one of plurality of dies 106₁, 106₂, 106₃, 106₄ . . . 106ₙ may each include various types of sensors, e.g. various types of accelerometers, gyrosensors, position sensors. At least one from the plurality of dies 106₁, 106₂, 106₃, 106₄ . . . 106ₙ may include semiconductor based sensors, e.g. sensors formed from a semiconductor material. At least one from the plurality of dies 106₁, 106₂, 106₃, 106₄ . . . 106ₙ, may include a sensor, wherein the sensor may include a sensing portion which responds to a stimulus, and one or more electronic components which may convert the response of the sensor portion to the stimulus into a signal, e.g. measurable signal.

At least one from the plurality of dies 106₁, 106₂, 106₃, 106₄ . . . 106ₙ, may include at least one from the following group of materials, the group consisting of: silicon, silicon carbide, gallium, gallium arsenide, carbon, graphene, germanium, silicon-germanium. At least one from the plurality of dies 106₁, 106₂, 106₃, 106₄ . . . 106ₙ may include a sensing portion wherein the sensing portion may include at least one from the following group of materials, the group consisting of: silicon, silicon carbide, gallium, gallium arsenide, carbon, graphene, germanium, silicon-germanium. At least one from the plurality of dies 106₁, 106₂, 106₃, 106₄ . . . 106ₙ may include a sensing portion, wherein the sensing portion may include nanomaterials, e.g. nanostructures, e.g. nanowires, e.g. nanotubes, e.g. nanocones. Examples include carbon nanotubes, single-walled carbon nanotubes, multi-walled carbon nanotubes, silicon nanowires, zinc nanowires.

At least one of plurality of dies 106₁, 106₂, 106₃, 106₄ . . . 106ₙ may include a microelectromechanical MEMS sensor.

At least one of plurality of dies 106₁, 106₂, 106₃, 106₄ . . . 106ₙ may include a chip which may include moving parts, e.g. tongue or membrane type structures. Deflection in the one or more moving parts may result in a change in a measurable parameter e.g. capacitance, e.g. piezoelectricity. Changes in a measurable parameter may suggest the size of movement. The one or more moving parts may include a structures on the micrometer scale, e.g. ranging from about 1 μm to about 1000 μm, e.g. from about 50 μm to about 500 μm, e.g. from about 100 μm to about 300 μm. Optional, the one or more moving parts may include a structures on the nanometer scale, e.g. ranging from about 1 nm to about 1000 nm, e.g. from about 50 nm to about 500 nm, e.g. from about 100 nm to about 300 nm.

At least one of plurality of dies 106₁, 106₂, 106₃, 106₄ . . . 106ₙ may include a speed and/or movement sensor. One of plurality of dies 106₁, 106₂, 106₃, 106₄ . . . 106ₙ may include a speed system wherein properties through the movement, e.g. speed, e.g. angle change, e.g. turning angle change may be varied and/or measured. The properties of the movement may result in a change in a measurable parameter e.g. a change in frequency, e.g. a change in electrical signal. Therefore, the determination of the extent and/or size of the movement may be possible.

At least one of plurality of dies 106₁, 106₂, 106₃, 106₄ . . . 106ₙ may include magnetic field sensors, e.g. gravity sensors, which may be used for position determination e.g. a compass.

According to various embodiments, microelectromechanical MEMS sensors and magnetic field sensors may be combined using a housing technology, wherein sensor chips of different technologies, e.g. die 106₁ and die 106₂ may be embedded in encapsulation material e.g. polymer material, and then electrically contacted through the application of electrically conductive portions and passivation e.g. dielectric material, die 106₁ and die 106₂ may be electrically contacted to each other. The arrangement of plurality of dies 106₁, 106₂, 106₃, 106₄ . . . 106ₙ, e.g. their electrical connection of the dies may be implementing according to different technologies, e.g. embedded wafer level ball grid array eWLB, e.g. BLADE, e.g. electrically connected and/or embedded in and/or over a printed circuit board. Furthermore, the combination of sensor chips of different technologies, e.g. die 106₁ and die 106₂ into an encapsulation material may allow batch testing of sensors of different technologies at wafer level, thereby simplifying the handling of sensor chips.

First die e.g. die 106₁ of the plurality of dies 106₁, 106₂, 106₃, 106₄ . . . 106ₙ, may include a chip, e.g. a semiconductor chip, implementing a first sensor technology, and a second die, e.g. die 106₂ of the plurality of dies 106₁, 106₂, 106₃, 106₄ . . . 106ₙ, may include a chip, e.g. a semiconductor chip, implementing a second sensor technology.

According to an embodiment, first die e.g. die 106₁ of the plurality of dies 106₁, 106₂, 106₃, 106₄ . . . 106ₙ, may include a magnetic sensor and second die, e.g. die 106₂ of the plurality of dies 106₁, 106₂, 106₃, 106₄ . . . 106ₙ may include a gyroscopic sensor system. One or more further dies of plurality of dies 106₁, 106₂, 106₃, 106₄ . . . 106ₙ, may each include at least one from the following group of devices, the group of devices consisting of: a logic device, a passive device, an active device.

According to another embodiment, first die e.g. die 106₁ of the plurality of dies 106₁, 106₂, 106₃, 106₄ . . . 106ₙ, may include a magnetic sensor and second die, e.g. die 10₆₂ of the plurality of dies 106₁, 106₂, 106₃, 106₄ . . . 106ₙ may include a gyroscopic sensor. Third die, e.g. die 1063 of the plurality of dies 106₁, 106₂, 106₃, 106₄ . . . 106ₙ, may include an acceleration sensor, e.g. an accelerometer. One or more further dies of plurality of dies 106₁, 106₂, 106₃, 106₄ . . . 106ₙ may each include at least one from the following group of devices, the group of devices consisting of: a logic device, a passive device, an active device.

According to another embodiment, first die e.g. die 106₁ of the plurality of dies 106₁, 106₂, 106₃, 106₄ . . . 106ₙ, may include a magnetic sensor and second die, e.g. die 106₂ of the plurality of dies 106₁, 106₂, 106₃, 106₄ . . . 106ₙ may include a gyroscopic sensor. Third die, e.g. die 106₃ of the plurality of dies 106₁, 106₂, 106₃, 106₄ . . . 106ₙ, may include an acceleration sensor. Fourth die, e.g. die 106₄ of the plurality of dies 106₁, 106₂, 106₃, 106₄ . . . 106ₙ, may include a pressure sensor. One or more further dies of plurality of dies 106₁, 106₂, 106₃, 106₄ . . . 106ₙ, may each include at least one from the following group of devices, the group of devices consisting of: a logic device, a passive device, an active device.

According to another embodiment, first die, e.g. die 106₁ of plurality of dies 106₁, 106₂, 106₃, 106₄ . . . 106ₙ may include a chip implementing a magnetic sensor technology. Second die, e.g. die 106₂ of plurality of dies 106₁, 106₂, 106₃, 106₄ . . . 106ₙ may include a chip implementing a mechanical sensor technology, e.g. a microelectromechanical sensor.

The term magnetic sensors may generally be used to describe one or more sensors, which may measures magnetic fields, e.g. selective magnetic field components. For example, magnetoresistive sensors, giant magnetoresistive GMR sensors, anisotropic magneto resistive AMR sensors.

Various embodiments describe inexpensive variants to produce a highly precise miniaturized sensors, e.g. miniaturized three-dimensional sensors, six-dimensional sensors, nine-dimensional sensors

Various embodiments provide, a combination of magnetic sensor chips, and motion sensor chips, e.g. gyrometers, accelerometers, in an embedded housing family, e.g. in a chip embedded package, e.g. a BLADE package, e.g. embedded in a circuit board, such as a printed circuit board.

Various embodiments provide a compass, e.g. three-dimensional compass. Various embodiments provide a chip embedded package including plurality of dies 106₁, 106₂, 106₃, 106₄ . . . 106ₙ, the chip embedded package including a compass, e.g. three-dimensional compass, the compass including a first die e.g. die 106₁ of the plurality of dies 106₁, 106₂, 106₃, 106₄ . . . 106ₙ, including a chip implementing a first sensor technology, e.g. a magnetic field sensor, and a second die, e.g. die 106₂ of the plurality of dies 106₁, 106₂, 106₃, 106₄ . . . 106ₙ, including a chip implementing a second sensor technology, e.g. a gyrometer.

Various embodiments provide movement sensor, e.g. a movement enabled controller for games, e.g. for three-dimensional consoles. Various embodiments provide a chip embedded package including plurality of dies 106₁, 106₂, 106₃, 106₄ . . . 106ₙ, the chip embedded package including a movement sensor, the movement sensor including a first die e.g. die 106₁ of the plurality of dies 106₁, 106₂, 106₃, 106₄ . . . 106ₙ, including a chip implementing a first sensor technology, e.g. a magnetic field sensor, and a second die, e.g. die 106₂ of the plurality of dies 106₁, 106₂, 106₃, 106₄ . . . 106ₙ, including a chip implementing a second sensor technology, e.g. a gyrometer, and optionally a third die, e.g. die 106₃ including a chip implementing a further sensor technology, e.g. an accelerometer.

Various embodiments provide a navigations system, e.g. a navigations assistant. Various embodiments provide a chip embedded package including plurality of dies 106₁, 106₂, 106₃, 106₄ . . . 106ₙ, the chip embedded package including a navigations system, the navigations system including a first die e.g. die 106₁ of the plurality of dies 106₁, 106₂, 106₃, 106₄ . . . 106ₙ, including a chip implementing a first sensor technology, e.g. a magnetic field sensor, and a second die, e.g. die 106₂ of the plurality of dies 106₁, 106₂, 106₃, 106₄ . . . 106ₙ, including a chip implementing a second sensor technology, e.g. a gyrometer, and optionally a third die, e.g. die 106₃ including a chip implementing a further sensor technology, e.g. an accelerometer, within package 402.

It may further be understood that chip embedded package may include a plurality of sensor packages 402, e.g. 402A, 402B, 402C; each sensor package 402 including a plurality of dies 106₁, 106₂, 106₃, 106₄ . . . 106ₙ; wherein a first die 106₁ of the plurality of dies 106₁, 106₂, 106₃, 106₄ . . . 106ₙ is a chip implementing a first sensor technology, and wherein a second die 106₂ of the plurality of dies 106₁, 106₂, 106₃, 106₄ . . . 106ₙ is a chip implementing a second sensor technology; and wherein the plurality of sensor packages 402 are molded with encapsulation material 107. In other words, the plurality of sensor packages 402 may be commonly molded to each other with encapsulation material 107, as shown in FIG. 3E.

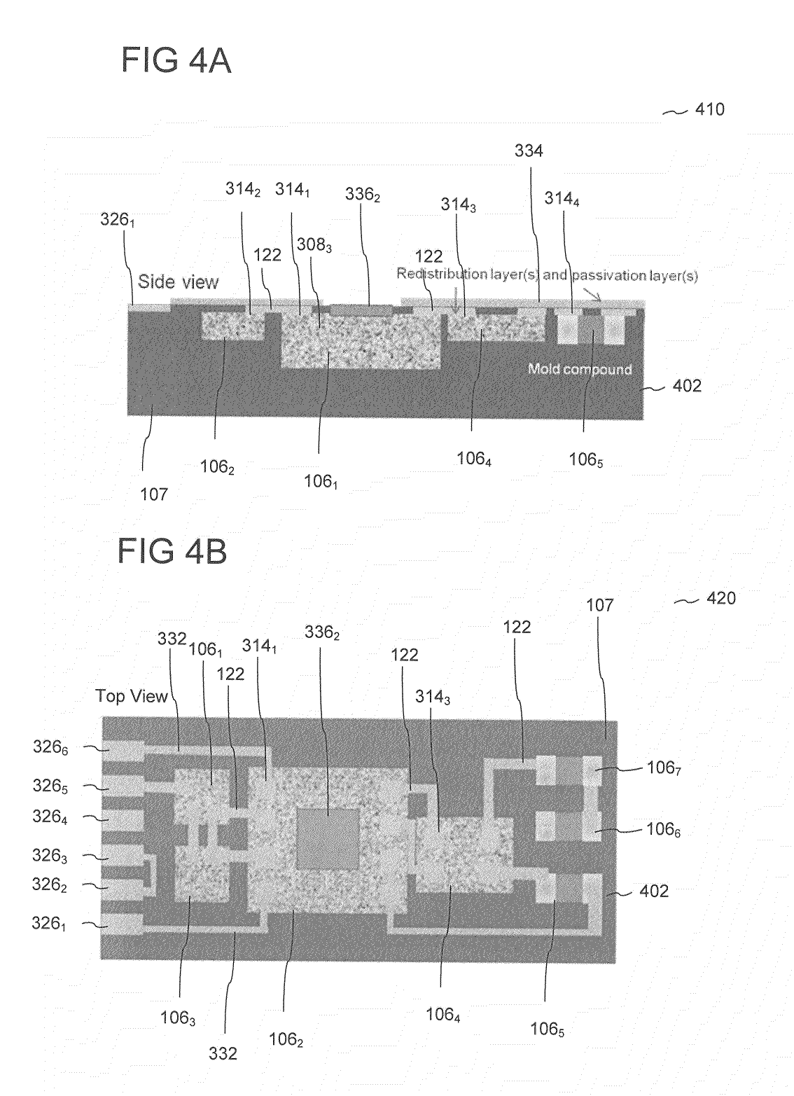

FIGS. 4A and 4B show a side view and a top view of part of a chip embedded package 402 according to an embodiment. FIG. 4A shows an individualized chip package 402 according to an embodiment. Chip package 402 may include one or more or all of the features of chip embedded package 302.

As shown in FIG. 4B, chip package 402 may include plurality of dies 106₁, 106₂, 106₃, 106₄, 106₅, 106₆, 106₇, wherein a first die e.g. die 106₁ of the plurality of dies 106₁, 106₂, 106₃, 106₄, 106₅, 106₆, 106₇, may include a chip implementing a first sensor technology, and wherein a second die, e.g. die 106₂ of the plurality of dies 106₁, 106₂, 106₃, 106₄, 106₅, 106₆, 106₇ may include a chip implementing a second sensor technology; and wherein plurality of dies 106₁, 106₂, 106₃, 106₄, 106₅, 106₆, 106₇, are molded with an encapsulation material 107.

One or more further dies, shown in FIG. 4B as further dies 106₄, 106₅, 106₆, 106₇ of plurality of dies 106₁, 106₂, 106₃, 106₄, 106₅, 106₆, 106₇, may each include at least one from the following group of devices, the group of devices consisting of: a logic device, a passive device, an active devices. First die e.g. die 106₁ and second die e.g. die 106₂ may be electrically interconnected, e.g. directly electrically interconnected via one or more electrically conductive portions 122. At least one of first die e.g. die 106₁ and second die e.g. die 106₂ may be electrically interconnected, directly and/or indirectly, to at least one of third die, e.g. die 106₃, fourth die, e.g. die 106₄, fifth die, e.g. die 106₅, sixth die, e.g. die 106₆, and seventh die e.g. die 106₇ via one or more electrically conductive portions 122. At least one of first die e.g. die 106₁ and second die e.g. die 106₂ may be electrically interconnected, directly and/or indirectly, via one or more contact pads formed over their front sides to one or more contact pads formed over the front sides of at least one of third die, e.g. die 106₃, fourth die, e.g. die 106₄, and fifth die (not shown). Second die e.g. die 106₂ and third die e.g. die 106₃ may be electrically interconnected via one or more electrically conductive portions 122. Chip package 402 may include one or more electrical contacts 326₁, 326₂, 326₃, 326₄, 326₅, 326₆, 326₇. At least one of first die e.g. die 106₁ and second die e.g. die 106₂ may be electrically interconnected, directly and/or indirectly, to one or more electrical contacts 326 via one or more further electrically conductive portions 332. Passivation layer 334 may be formed over one or more electrically conductive portions 122, and over the top sides 308 of plurality of dies 106₁, 106₂, 106₃, 106₄, 106₅, 106₆, 106₇.

According to an embodiment, First die, e.g. die 106₁ may include a gyro sensor. Second die, e.g. die 106₂ may include a pressure sensor. Third die, e.g. die 106₃ may include a hall sensor.

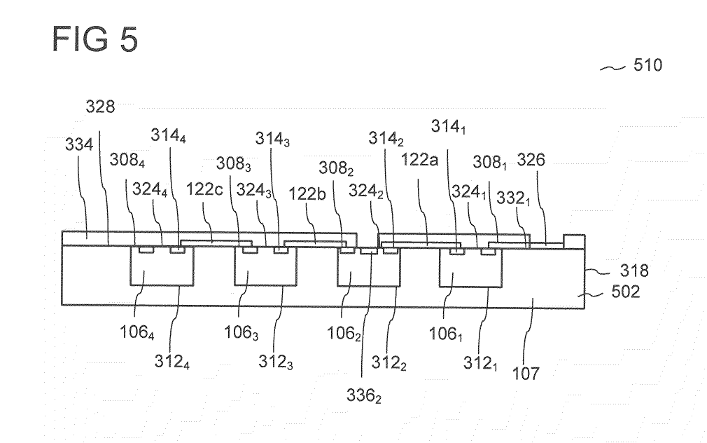

FIG. 5 shows chip embedded package 502 according to an embodiment. Chip embedded package 502 may include one or more or all of the features described with respect to at least one of chip embedded package 102, chip embedded package 302 and chip embedded package 402.

Chip embedded package 502 may include plurality of dies 106₁, 106₂, 106₃, 106₄ . . . 106ₙ; encapsulation material 107 at least partially surrounding the plurality of dies 106₁, 106₂, 106₃, 106₄ . . . 106ₙ, and separating plurality of dies 106₁, 106₂, 106₃, 106₄ . . . 106ₙ, from each other, wherein a first die, e.g. 106₁ of plurality of dies 106₁, 106₂, 106₃, 106₄ . . . 106ₙ, may include a first sensor implementing a first sensor technology, and wherein a second die, e.g. 106₂ of the plurality of dies may include a second sensor implementing a second sensor technology.

Chip embedded package 502 may further include one or more electrically conductive portions 122a, 122b, 122c formed over first side 328 of chip embedded package 502; wherein at least one electrically conductive portion of the one or more electrically conductive portions 122a, 122b, 122c electrically connects the first die, e.g. 106₁ to the second die, e.g. 106₂.

At least one electrically conductive portion 122a of the one or more electrically conductive portions 122a, 122b, 122c may be formed over a first die top side 308₁ and second die top side 308₂.

At least one further electrically conductive portion of the one or more electrically conductive portions 122a, 122b, 122c may electrically connect at least one of the first die, e.g. 106₁ the second die, e.g. 106₂ to one or more further dies of the plurality of dies.

One or more further dies of the plurality of dies 106₁, 106₂, 106₃, 106₄ . . . 106ₙ, may each include at least one from the following group of devices, the group of devices consisting of: a logic device, a passive device, an active device. The logic device may include at least one from the following group of the devices, the group consisting of: an application specific integrated circuit ASIC, a driver, a controller, a sensor. The passive device may include at least one from the following group of the devices, the group consisting of: resistors, capacitors, inductors. The active device may include at least one from the following group of the devices, the group consisting of: semiconductor devices, transistors, power devices, power transistors, MOS transistors, bipolar transistors, field effect transistors, insulated gate bipolar transistors, thyristors, MOS controlled thyristors, silicon controlled rectifiers, schottky diodes, silicon carbide diodes, gallium nitride devices, aluminum nitride devices.

Chip embedded package 502 may further include one or more electrical contacts 326 formed over the first side 328 of the chip embedded package; wherein the one or more electrical contacts may electrically connected to at least one of the first die, e.g. die 106₁ and the second die, e.g. die 106₂.

Chip embedded package may further include one or more electrically insulating portions 334 formed over the one or more electrically conductive portions 122a, 122b, 122c.

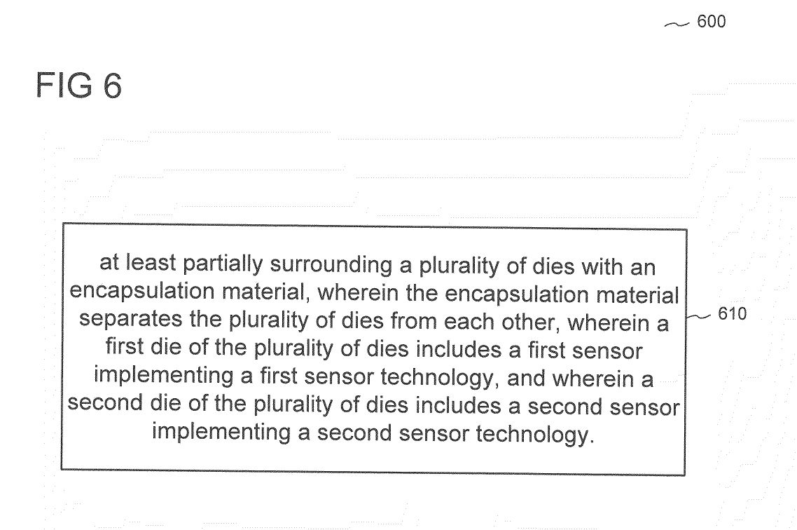

FIG. 6 shows a method for manufacturing a chip embedded package, the method including:

at least partially surrounding a plurality of dies with an encapsulation material, wherein the encapsulation material separates the plurality of dies from each other, wherein a first die of the plurality of dies includes a first sensor implementing a first sensor technology, and wherein a second die of the plurality of dies includes a second sensor implementing a second sensor technology (in 610).

Various embodiments provide chip embedded package, the chip embedded package including: a plurality of dies; wherein a first die of the plurality of dies is a chip implementing a first sensor technology, and wherein a second die of the plurality of dies is a chip implementing a second sensor technology; and wherein the plurality of dies are molded with an encapsulation material; wherein at least one of the first die and the second die includes a film interconnect.

According to an embodiment, the chip embedded package further includes a carrier; wherein the plurality of dies are disposed over the carrier; and wherein the plurality of dies are molded with an encapsulation material over the carrier.

According to an embodiment, the carrier includes an electrically insulating material or an electrically conductive and/or semiconductive material, the electrically insulating material including at least one from the following group of materials, the group consisting of: plastic, glass, metal, silicon, an organic material.

According to an embodiment, at least one of the first sensor technology and the second sensor technology includes a sensor technology from the following group of sensor technologies, the group consisting of: magnetic sensor technology, gyroscopic sensor technology, motion sensor technology, acceleration sensor technology.

According to an embodiment, at least one of the first sensor technology and the second sensor technology includes a sensor technology from the following group of sensor technologies, the group consisting of: magnetic sensor technology, gyroscopic sensor technology, motion sensor technology, acceleration sensor technology, pressure sensor technology, photosensor technology, gas sensor technology, chemical sensor technology, biological sensor technology, current sensor technology, biometric sensor technology.

According to an embodiment, the first sensor technology is different from the second sensor technology.

According to an embodiment, at least one of the first sensor technology and the second sensor technology includes at least one sensor from the following group of sensors, the group consisting of: a mechanical sensor, an electrical sensor, and electromechanical sensor, a microelectromechanical sensor.

According to an embodiment, one or more further dies of the plurality of dies each includes at least one from the following group of devices, the group of devices consisting of: a logic device, a passive device, an active devices.

According to an embodiment, the logic device includes at least one from the following group of the devices, the group consisting of: an application specific integrated circuit ASIC, a driver, a controller, a sensor.

According to an embodiment, the passive device includes at least one from the following group of the devices, the group consisting of: a resistor, a capacitor, and inductor.

According to an embodiment, the active device includes at least one from the following group of the devices, the group consisting of: semiconductor devices, transistors, power devices, power transistors, MOS transistors, bipolar transistors, field effect transistors, insulated gate bipolar transistors, thyristors, MOS controlled thyristors, silicon controlled rectifiers, schottky diodes, silicon carbide diodes, gallium nitride devices, aluminum nitride devices.

According to an embodiment, at least one from the plurality of dies includes at least one from the following group of materials, the group consisting of: silicon, silicon carbide, gallium, gallium arsenide, carbon, graphene, germanium, silicon-germanium.

According to an embodiment, the encapsulation material includes at least one from the following group of materials, the group consisting of: filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

Various embodiments provide, a chip embedded package including: a plurality of dies; an encapsulation material at least partially surrounding the plurality of dies and separating the plurality of dies from each other, wherein a first die of the plurality of dies includes a first sensor implementing a first sensor technology, and wherein a second die of the plurality of dies includes a second sensor implementing a second sensor technology.

According to an embodiment, the chip embedded package further includes one or more electrically conductive portions formed over a first side of the chip embedded package; wherein at least one electrically conductive portion of the one or more electrically conductive portions electrically connects the first die to the second die.

According to an embodiment, the at least one electrically conductive portion of the one or more electrically conductive portions is formed over a first die top side and second die top side.

According to an embodiment, at least one further electrically conductive portion of the one or more electrically conductive portions electrically connects at least one of the first die and the second die to one or more further dies of the plurality of dies.

According to an embodiment, the one or more further dies of the plurality of dies each includes at least one from the following group of devices, the group of devices consisting of: a logic device, a passive device, an active device.

According to an embodiment, the logic device includes at least one from the following group of the devices, the group consisting of: an application specific integrated circuit ASIC, a driver, a controller, a sensor.

According to an embodiment, the passive device includes at least one from the following group of the devices, the group consisting of: resistors, capacitors, inductors.

According to an embodiment, the active device includes at least one from the following group of the devices, the group consisting of: semiconductor devices, transistors, power devices, power transistors, MOS transistors, bipolar transistors, field effect transistors, insulated gate bipolar transistors, thyristors, MOS controlled thyristors, silicon controlled rectifiers, schottky diodes, silicon carbide diodes, gallium nitride devices, aluminum nitride devices.

According to an embodiment, the chip embedded package further includes one or more electrically conductive contact pads formed over the first side of the chip embedded package; wherein the one or more electrically conductive contact pads are electrically connected to at least one of the first die and the second die.

According to an embodiment, the chip embedded package further includes one or more electrically insulating portions formed over the one or more electrically conductive portions.

Various embodiments provide a method for manufacturing a chip embedded package, the method including: disposing a plurality of dies over a carrier, wherein a first die of the plurality of dies is a chip implementing a first sensor technology, and wherein a second die of the plurality of dies is a chip implementing a second sensor technology; commonly molding the plurality of dies with an encapsulation material over the carrier.

According to an embodiment, the method further includes forming one or more electrically conductive portions over a first side of the chip embedded package; wherein at least one electrically conductive portion of the one or more electrically conductive portions electrically connects the first die to the second die, and wherein at least one further electrically conductive portion of the one or more electrically conductive portions electrically connects at least one of the first die and the second die to one or more further dies of the plurality of dies.

According to embodiment, the method further includes forming one or more electrically conductive contact pads over the first side of the chip embedded package and electrically connecting the one or more electrically conductive contact pads to at least one of the first die and the second die; and forming one or more electrically insulating portions over the one or more electrically conductive portions.

According to embodiment, the method further includes connecting the one or more electrically conductive contact pads to an external electrical circuit for testing the plurality of dies; and subsequently separating the plurality of dies wherein a separated portion includes the first die and the second die.

Various embodiments provide a method for manufacturing a chip embedded package, the method including: at least partially surrounding a plurality of dies with an encapsulation material, wherein the encapsulation material separates the plurality of dies from each other, and it is wherein a first die of the plurality of dies includes a first sensor implementing a first sensor technology, and wherein a second die of the plurality of dies includes a second sensor implementing a second sensor technology.

Various embodiments provide a chip embedded package, including: a plurality of sensor packages; each sensor package including a plurality of dies; wherein a first die of the plurality of dies is a chip implementing a first sensor technology, and wherein a second die of the plurality of dies is a chip implementing a second sensor technology; and wherein the plurality of sensor packages are molded with an encapsulation material.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip embedded package, comprising:
a plurality of dies;
wherein a first die of the plurality of dies is a chip implementing a first sensor technology, and wherein a second die of the plurality of dies is a chip implementing a second sensor technology; and
wherein the plurality of dies are molded with an encapsulation material;
wherein at least one of the first die and the second die comprises a film interconnect.

2. The chip embedded package according to claim 1, further comprising:
a carrier;
wherein the plurality of dies are disposed over the carrier; and
wherein the plurality of dies are molded with an encapsulation material over the carrier.

3. The chip embedded package according to claim 1,
wherein at least one of the first sensor technology and the second sensor technology comprises a sensor technology from the following group of sensor technologies, the group consisting of: magnetic sensor technology, gyroscopic sensor technology, motion sensor technology, acceleration sensor technology.

4. The chip embedded package according to claim 1,
wherein at least one of the first sensor technology and the second sensor technology comprises a sensor technology from the following group of sensor technologies, the group consisting of: magnetic sensor technology, gyroscopic sensor technology, motion sensor technology, acceleration sensor technology, pressure sensor technology, photosensor technology, gas sensor technology, chemical sensor technology, biological sensor technology, current sensor technology, biometric sensor technology.

5. The chip embedded package according to claim 1,
wherein the first sensor technology is different from the second sensor technology.

6. The chip embedded package according to claim 1,
wherein at least one of the first sensor technology and the second sensor technology comprises at least one sensor from the following group of sensors, the group consisting of: a mechanical sensor, an electrical sensor, and electromechanical sensor, a microelectromechanical sensor.

7. The chip embedded package according to claim 1,
wherein one or more further dies of the plurality of dies each comprises at least one from the following group of devices, the group of devices consisting of: a logic device, a passive device, an active devices.

8. The chip embedded package according to claim 7,
wherein the logic device comprises at least one from the following group of the devices, the group consisting of: an application specific integrated circuit ASIC, a driver, a controller, a sensor.

9. The chip embedded package according to claim 7,
wherein the passive device comprises at least one from the following group of the devices, the group consisting of: a resistor, a capacitor, and inductor.

10. The chip embedded package according to claim 7,
wherein the active device comprises at least one from the following group of the devices, the group consisting of: semiconductor devices, transistors, power devices, power transistors, MOS transistors, bipolar transistors, field effect transistors, insulated gate bipolar transistors, thyristors, MOS controlled thyristors, silicon controlled rectifiers, schottky diodes, silicon carbide diodes, gallium nitride devices, aluminum nitride devices.

11. The chip embedded package according to claim 1,
wherein at least one from the plurality of dies comprises at least one from the following group of materials, the group consisting of: silicon, silicon carbide, gallium, gallium arsenide, carbon, graphene, germanium, silicon-germanium.

12. The chip embedded package according to claim 1,
wherein the encapsulation material comprises at least one from the following group of materials, the group consisting of: filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

13. A chip embedded package comprising:
a plurality of dies;
an encapsulation material at least partially surrounding the plurality of dies and separating the plurality of dies from each other,
wherein a first die of the plurality of dies comprises a first sensor implementing a first sensor technology, and wherein a second die of the plurality of dies comprises a second sensor implementing a second sensor technology.

14. The chip embedded package according to claim 13, further comprising
one or more electrically conductive portions formed over a first side of the chip embedded package;
wherein at least one electrically conductive portion of the one or more electrically conductive portions electrically connects the first die to the second die.

15. The chip embedded package according to claim 14,
wherein the at least one electrically conductive portion of the one or more electrically conductive portions is formed over a first die top side and second die top side.

16. The chip embedded package according to claim 14,
wherein at least one further electrically conductive portion of the one or more electrically conductive portions electrically connects at least one of the first die and the second die to one or more further dies of the plurality of dies.

17. The chip embedded package according to claim 16,
wherein the one or more further dies of the plurality of dies each comprises at least one from the following group of devices, the group of devices consisting of: a logic device, a passive device, an active device.

18. The chip embedded package according to claim 17,
wherein the logic device comprises at least one from the following group of the devices, the group consisting of: an application specific integrated circuit ASIC, a driver, a controller, a sensor.

19. The chip embedded package according to claim 17,
wherein the passive device comprises at least one from the following group of the devices, the group consisting of: resistors, capacitors, inductors.

20. The chip embedded package according to claim 17,
wherein the active device comprises at least one from the following group of the devices, the group consisting of: semiconductor devices, transistors, power devices, power transistors, MOS transistors, bipolar transistors, field effect transistors, insulated gate bipolar transistors, thyristors, MOS controlled thyristors, silicon controlled rectifiers, schottky diodes, silicon carbide diodes, gallium nitride devices, aluminum nitride devices.

21. The chip embedded package according to claim 14, further comprising
one or more electrical contacts formed over the first side of the chip embedded package;
wherein the one or more electrical contacts are electrically connected to at least one of the first die and the second die.

22. The chip embedded package according to claim 14, further comprising
one or more electrically insulating portions formed over the one or more electrically conductive portions.

23. A method for manufacturing a chip embedded package, the method comprising:
molding a plurality of die with an encapsulation material, wherein a first die of the plurality of dies is a chip implementing a first sensor technology, and wherein a second die of the plurality of dies is a chip implementing a second sensor technology; and
wherein at least one of the first die and the second die comprises a film interconnect.

24. The method according to claim 23, further comprising
forming one or more electrically conductive portions over a first side of the chip embedded package;
wherein at least one electrically conductive portion of the one or more electrically conductive portions electrically connects the first die to the second die, and wherein at least one further electrically conductive portion of the one or more electrically conductive portions electrically connects at least one of the first die and the second die to one or more further dies of the plurality of dies.

25. The method according to claim 24, further comprising
forming one or more electrical contacts over the first side of the chip embedded package and electrically connecting the one or more electrical contacts to at least one of the first die and the second die; and
forming one or more electrically insulating portions over the one or more electrically conductive portions.

26. The method according to claim 25, further comprising
connecting the one or more electrical contacts to an external electrical circuit for testing the plurality of dies; and
subsequently separating the plurality of dies wherein a separated portion includes the first die and the second die.

27. A method for manufacturing a chip embedded package, the method comprising:
at least partially surrounding a plurality of dies with an encapsulation material, wherein the encapsulation material separates the plurality of dies from each other,
wherein a first die of the plurality of dies comprises a first sensor implementing a first sensor technology, and wherein a second die of the plurality of dies comprises a second sensor implementing a second sensor technology.

28. A chip embedded package, comprising:
a plurality of sensor packages;
each sensor package comprising
a plurality of dies;
wherein a first die of the plurality of dies is a chip implementing a first sensor technology, and wherein a second die of the plurality of dies is a chip implementing a second sensor technology; and
wherein the plurality of sensor packages are molded with an encapsulation material.
